(19) United States
(12) Patent Application Publication
(10) Pub. No.: US 2009/0253081 A1
(43) Pub. Date: Oct. 8, 2009

(54) Process for Shrinking Dimensions Between Photoresist Pattern Comprising a Pattern Hardening Step

(76) Inventors: David Abdallah, Bernardsville, NJ (US); Ralph R. Dammel, Flemington, NJ (US); Victor Monreal, Breinigsville, PA (US)

Correspondence Address: SANGYA JAIN;AZ ELECTRONIC MATERIALS USA CORP., 70 MEISTER AVENUE, SOMERVILLE, NJ, 08876, US

(21) Appl. No.: 12/061,111

(22) Filed: Apr. 2, 2008

(51) Int. Cl. G03F 7/40

(52) U.S. Cl. 430/324

(57) ABSTRACT

A process for forming a photoresist pattern on a device, comprising; a) forming a layer of first photoresist on a substrate from a first photoresist composition; b) imagewise exposing the first photoresist; c) developing the first photoresist to form a first photoresist pattern; d) treating the first photoresist pattern with a hardening compound comprising at least 2 amino (NH₂) groups, thereby forming a hardened first photoresist pattern; e) forming a second photoresist layer on the region of the substrate including the hardened first photoresist pattern from a second photoresist composition; f) flood exposing the second photoresist; and, g) developing the flood exposed second photoresist to form a photoresist pattern with increased dimensions and reduced spaces.

### TECHNICAL FIELD

The present invention relates to a process for shrinking the space dimensions between patterned photoresist features by increasing the dimensions of the photoresist pattern.

### BACKGROUND ART

The densification of integrated circuits in semiconductor technology has been accompanied by a need to manufacture very fine interconnections within these integrated circuits. Ultra-fine patterns are typically created by forming patterns in a photoresist coating using photolithographic techniques. Generally, in these processes, a thin coating of a film of a photoresist composition is first applied to a substrate material, such as silicon wafers used for making integrated circuits. The coated substrate is then baked to evaporate any solvent in the photoresist composition and to fix the coating onto the substrate. The baked coated surface of the substrate is next subjected to an image-wise exposure to radiation. This radiation exposure causes a chemical transformation in the exposed areas of the coated surface. Visible light, ultraviolet (UV) light, electron beam and X-ray radiant energy are radiation types commonly used today in microlithographic processes. After this image-wise exposure, the coated substrate is treated with a developer solution to dissolve and remove either the radiation-exposed or the unexposed areas of the photoresist.

Miniaturization of integrated circuits requires the printing of narrower and narrower dimensions within the photoresist. Various technologies have been developed to shrink the dimensions to be printed by the photoresist, examples of such technologies are, multilevel coatings, antireflective coatings, phase-shift masks, photoresists which are sensitive at shorter and shorter wavelengths, etc.

One important process for printing smaller dimensions relies on the technique of forming a thin layer on top of the image of the photoresist pattern, which widens the photoresist feature and reduces the dimension of the space between adjacent photoresist patterns. This narrowed space can be used to etch and define the substrate or be used to deposit materials, such as metals. This two step technique allows much smaller dimensions to be defined as part of the manufacturing process for microelectronic devices, without the necessity of reformulating new photoresist chemistries. The top coating layer or shrink material may be an inorganic layer such as a dielectric material, or it may be organic such as a crosslinkable polymeric material.

Dielectric shrink materials are described in U.S. Pat. No. 5,863,707, and comprise silicon oxide, silicon nitride, silicon oxynitride, spin on material or chemical vapor deposited material. Organic polymeric coatings are described in U.S. Pat. No. 5,858,620, where such coatings undergo a crosslinking reaction in the presence of an acid, thereby adhering to the photoresist surface, but are removed where the top shrink coating has not been crosslinked. U.S. Pat. No. 5,858,620 discloses a method of manufacturing a semiconductor device, where the substrate has a patterned photoresist which is coated with a top layer, the photoresist is then exposed to light and heated so that the photogenerated acid in the photoresist diffuses through the top layer and can then crosslink the top layer. The extent to which the acid diffuses through the top coat determines the thickness of the crosslinked layer. The portion of the top layer that is not crosslinked is removed using a solution that can dissolve the polymer.

The present invention relates to a novel process for shrinking the space in a photoresist pattern comprising forming a photoresist pattern, hardening or freezing the photoresist pattern, forming a photoresist coating over the hardened imaged photoresist pattern, flood exposing the photoresist coating with a suitable exposure dose, and developing the second photoresist, thereby forming a pattern which has increased photoresist dimensions but the spaces between the photoresist features is reduced. Thus the object of the present invention is to increase the dimensional thickness of the photoresist pattern such that narrow spaces can be defined. The process is particularly useful for coating over photoresists sensitive at 248 nm, 193 nm and 157 nm. The process leads to improved pattern definition, higher resolution, low defects, and stable pattern formation of imaged photoresist.

### BRIEF DESCRIPTION OF DRAWING

FIG. 1 illustrates the imaging process using hardening step and the flood exposure step.

FIG. 2 shows a design of a photoresist hardening chamber.

FIG. 3 shows the effect of flood exposure dose on (critical dimensions of the photoresist pattern (CD).

### SUMMARY OF THE INVENTION

The present invention relates to a process for forming a photoresist pattern on a device, comprising; a) forming a layer of first photoresist on a substrate from a first photoresist composition; b) imagewise exposing the first photoresist; c) developing the first photoresist to form a first photoresist pattern; d) treating the first photoresist pattern with a hardening compound comprising at least 2 amino (NH₂) groups, thereby forming a hardened first photoresist pattern; e) forming a second photoresist layer, on the region of the substrate including the hardened first photoresist pattern, from a second photoresist composition; f) flood exposing the second photoresist; and, g) developing the flood exposed second photoresist to form a photoresist pattern with increased dimensions and reduced spaces.

The process further includes a hardening compound having structure (1),

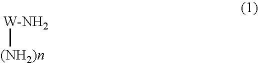

where, W is a C₁-C₈ alkylene, and n is 1-3.

### DETAILED DESCRIPTION OF THE INVENTION

The present invention relates to a process for imaging fine patterns on a microelectronic device using double exposure of two photoresist layers, where the first layer is imagewise exposed and hardened or frozen, and the second photoresist coating is flood exposed and developed. The process comprises patterning of a first photoresist layer followed by a photoresist hardening step and then a second flood exposure of photoresist which forms a thickener pattern than the first photoresist pattern. The flood exposure may use any of the radiation sources described herein. The double exposure steps allows for an increase in photoresist dimensions as compared to a single patterning step. The inventive process is illustrated in FIG. 1. The inventive process comprises, a) forming a layer of first photoresist on a substrate from a first photoresist composition; b) imagewise exposing the first photoresist; c) developing the first photoresist to form a first photoresist pattern; d) treating or freezing the first photoresist pattern with a hardening compound comprising at least 2 amino (NH₂) groups, thereby forming a hardened first photoresist pattern; e) forming a second photoresist layer, on the region of the substrate including the hardened first photoresist pattern, from a second photoresist composition; f) flood exposing the second photoresist with a suitable exposure energy; and, g) developing the second photoresist pattern, thereby forming a photoresist pattern with increased dimensions.

The first layer of photoresist is imaged on a substrate using known techniques of forming a layer of a photoresist from a photoresist composition. The photoresist may be positive acting or negative acting. The photoresist comprises a polymer, photoacid generator a solvent, and may further comprise additives such as basic qenchers, surfactants, dyes and crosslinkers. An edge bead remover may be applied after the coating steps to clean the edges of the substrate using processes well known in the art. The photoresist layer is softbaked to remove the photoresist solvent. The photoresist layer is then imagewise exposed through a mask or reticle, optionally post exposure baked, and then developed using an aqueous alkaline developer. After the coating process, the photoresist can be imagewise exposed using any imaging radiations such as those ranging from 13 nm to 450 nm. Typical radiation sources are 157 nm, 193 nm, 248 nm, 365 nm and 436 nm. The exposure may be done using typical dry exposure or may be done using immersion lithography. The exposed photoresist is then developed in an aqueous developer to form the photoresist pattern. The developer is preferably an aqueous alkaline solution comprising, for example, tetramethyl ammonium hydroxide. An optional heating step can be incorporated into the process prior to development and after exposure. The exact conditions of coating, baking, imaging and developing are determined by the photoresist used.

The substrates over which the photoresist coating is formed can be any of those typically used in the semiconductor industry. Suitable substrates include, without limitation, silicon, silicon substrate coated with a metal surface, copper coated silicon wafer, copper, aluminum, polymeric resins, silicon dioxide, metals, doped silicon dioxide, silicon nitride, tantalum, polysilicon, ceramics, aluminum/copper mixtures; gallium arsenide and other such Group III/V compounds. The substrate may comprise any number of layers made from the materials described above. These substrates may further have a single or multiple coating of antireflective coatings prior to the coating of the photoresist layer. The coatings may be inorganic, organic or mixture of these. The coatings may be siloxane or silicone on top of a high carbon content antireflective coating. Any types of antireflective coatings which are known in the art may be used.

The present process is particularly suited to deep ultraviolet exposure. To date, there are several major deep ultraviolet (uv) exposure technologies that have provided significant advancement in miniaturization, and these are radiation of 248 nm, 193 nm, 157 and 13.5 nm. Chemically amplified photoresist are typically used. They may be negative or positive. Photoresists for 248 nm have typically been based on substituted polyhydroxystyrene and its copolymers/onium salts, such as those described in U.S. Pat. No. 4,491,628 and U.S. Pat. No. 5,350,660. On the other hand, photoresists for exposure below 200 nm require non-aromatic polymers since aromatics are opaque at this wavelength. U.S. Pat. No. 5,843,624 and U.S. Pat. No. 6,866,984 disclose photoresists useful for 193 nm exposure. Generally, polymers containing alicyclic hydrocarbons are used for photoresists for exposure below 200 nm. Alicyclic hydrocarbons are incorporated into the polymer for many reasons, primarily since they have relatively high carbon to hydrogen ratios which improve etch resistance, they also provide transparency at low wavelengths and they have relatively high glass transition temperatures. U.S. Pat. No. 5,843,624 discloses polymers for photoresist that are obtained by free radical polymerization of maleic anhydride and unsaturated cyclic monomers. Any of the known types of 193 nm photoresists may be used, such as those described in U.S. Pat. No. 6,447,980 and U.S. Pat. No. 6,723,488, and incorporated herein by reference.

Two basic classes of photoresists sensitive at 157 nm, and based on fluorinated polymers with pendant fluoroalcohol groups, are known to be substantially transparent at that wavelength. One class of 157 nm fluoroalcohol photoresists is derived from polymers containing groups such as fluorinated-norbornenes, and are homopolymerized or copolymerized with other transparent monomers such as tetrafluoroethylene (U.S. Pat. No. 6,790,587, and U.S. Pat. No. 6,849,377) using either metal catalyzed or radical polymerization. Generally, these materials give higher absorbencies but have good plasma etch resistance due to their high alicyclic content. More recently, a class of 157 nm fluoroalcohol polymers was described in which the polymer backbone is derived from the cyclopolymerization of an asymmetrical diene such as 1,1,2,3,3-pentafluoro-4-trifluoromethyl-4-hydroxy-1,6-heptadiene (Shun-ichi Kodama et al Advances in Resist Technology and Processing XIX, Proceedings of SPIE Vol. 4690 p76 2002; U.S. Pat. No. 6,818,258) or copolymerization of a fluorodiene with an olefin (U.S. Pat. No. 6,916,590). These materials give acceptable absorbance at 157 nm, but due to their lower alicyclic content as compared to the fluoro-norbornene polymer, have lower plasma etch resistance. These two classes of polymers can often be blended to provide a balance between the high etch resistance of the first polymer type and the high transparency at 157 nm of the second polymer type. Photoresists that absorb extreme ultraviolet radiation (EUV) of 13.5 nm are also useful and are known in the art. Photoresists sensitive to 365 nm and 436 nm may also be used. At the present time 193 nm photoresists are preferred.

The solid components of the photoresist composition are mixed with a solvent or mixtures of solvents that dissolve the solid components of the photoresist. Suitable solvents for the photoresist may include, for example, a glycol ether derivative such as ethyl cellosolve, methyl cellosolve, propylene glycol monomethyl ether, diethylene glycol monomethyl ether, diethylene glycol monoethyl ether, dipropylene glycol dimethyl ether, propylene glycol n-propyl ether, or diethylene glycol dimethyl ether; a glycol ether ester derivative such as ethyl cellosolve acetate, methyl cellosolve acetate, or propylene glycol monomethyl ether acetate; carboxylates such as ethyl acetate, n-butyl acetate and amyl acetate; carboxylates of di-basic acids such as diethyloxylate and diethylmalonate; dicarboxylates of glycols such as ethylene glycol diacetate and propylene glycol diacetate; and hydroxy carboxylates such as methyl lactate, ethyl lactate, ethyl glycolate, and ethyl-3-hydroxy propionate; a ketone ester such as methyl pyruvate or ethyl pyruvate; an alkoxycarboxylic acid ester such as methyl 3-methoxypropionate, ethyl 3-ethoxypropionate, ethyl 2-hydroxy-2-methylpropionate, or methylethoxypropionate; a ketone derivative such as methyl ethyl ketone, acetyl acetone, cyclopentanone, cyclohexanone or 2-heptanone; a ketone ether derivative such as diacetone alcohol methyl ether; a ketone alcohol derivative such as acetol or diacetone alcohol; a ketal or acetal like 1,3 dioxalne and diethoxypropane; lactones such as butyrolactone; an amide derivative such as dimethylacetamide or dimethylformamide, anisole, and mixtures thereof. Typical solvents for photoresist, used as mixtures or alone, that can be used, without limitation, are propylene glycol monomethyl ether acetate (PGMEA), propylene gycol monomethyl ether (PGME), and ethyl lactate (EL), 2-heptanone, cyclopentanone, cyclohexanone, and gamma butyrolactone, but PGME, PGMEA and EL or mixtures thereof are preferred. Solvents with a lower degree of toxicity, good coating and solubility properties are generally preferred.

In one embodiment of the process a photoresist sensitive to 193 nm is used. The photoresist comprises a polymer, a photoacid generator, and a solvent. The polymer is an (meth)acrylate polymer which is insoluble in an aqueous alkaline developer. Such polymers may comprise units derived from the polymerization of monomers such as alicyclic (meth)acrylates, mevalonic lactone methacrylate, 2-methyl-2-adamantyl methacrylate, 2-adamantyl methacrylate (AdMA), 2-methyl-2-adamantyl acrylate (MAdA), 2-ethyl-2-adamantyl methacrylate (EAdMA), 3,5-dimethyl-7-hydroxy adamantyl methacrylate (DMHAdMA), isoadamantyl methacrylate, hydroxy-1-methacryloxyadamatane (HAdMA; for example, hydroxy at the 3- position), hydroxy-1-adamantyl acrylate (HADA; for example, hydroxy at the 3- position), ethylcyclopentylacrylate (ECPA), ethylcyclopentylmethacrylate (ECPMA), tricyclo[5,2,1,0^{2,6}]deca-8-yl methacrylate (TCDMA), 3,5-dihydroxy-1-methacryloxyadamantane (DHAdMA), β-methacryloxy-γ-butyrolactone, α- or β-gamma-butyrolactone methacrylate (either α- or β-GBLMA), 5-methacryloyloxy-2,6-norbornanecarbolactone (MNBL), 5-acryloyloxy-2,6-norbornanecarbolactone (ANBL), isobutyl methacrylate (IBMA), α-gamma-butyrolartone acrylate (α-GBLA), spirolactone (meth)acrylate, oxytricyclodecane (meth)acrylate, adamantane lactone (meth)acrylate, and α-methacryloxy-γ-butyrolactone, among others. Examples of polymers formed with these monomers include poly(2-methyl-2-adamantyl methacrylate-co-2-ethyl-2-adamantyl methacrylate-co-3-hydroxy-1-methacryloxyadamantane-co-α-gamma-butyrolactone methacrylate); poly(2-ethyl-2-adamantyl methacrylate-co-3-hydroxy-1-methacryloxyadamantane-co-β-gamma-butyrolactone methacrylate); poly(2-methyl-2-adamantyl methacrylate-co-3-hydroxy-1-methacryloxyadamantane-co-β-gamma-butyrolactone methacrylate); poly(t-butyl norbornene carboxylate-co-maleic anhydride-co-2-methyl-2-adamantyl methacrylate-co-β-gamma-butyrolactone methacrylate-co-methacryloyloxy norbornene methacrylate); poly(2-methyl-2-adamantyl methacrylate-co-3-hydroxy-1-methacryloxyadamantane-co-β-gamma-butyrolactone methacrylate-co-tricyclo[5,2,1,0^{2,6}]deca-8-yl methacrylate); poly(2-ethyl-2-adamantyl methacrylate-co-3-hydroxy-1-adamantyl acrylate-co-β-gamma-butyrolactone methacrylate); poly(2-ethyl-2-adamantyl methacrylate-co-3-hydroxy-1-adamantyl acrylate-co-α-gamma-butyrolactone methacrylate-co-tricyclo[5,2,1,0^{2,6}]deca-8-yl methacrylate); poly(2-methyl-2-adamantyl methacrylate-co-3,5-dihydroxy-1-methacryloxyadamantane-co-α-gamma-butyrolactone methacrylate); poly(2-methyl-2-adamantyl methacrylate-co-3,5-dimethyl-7-hydroxy adamantyl methacrylate-co-α-gamma-butyrolactone methacylate); poly(2-methyl-2-adamantyl acrylate-co-3-hydroxy-1-methacryloxyadamantane-co-α-gamma-butyrolactone methacrylate); poly(2-methyl-2-adamantyl methacrylate-co-3-hydroxy-1-methacryloxyadamantane-co-β-gamma-butyrolactone methacrylate-co-tricyclo[5,2,1,0^{2,6}]deca-8-yl methacrylate); poly(2-methyl-2-adamantyl methacrylate-co-β-gamma-butyrolactone methacrylate-co-3-hydroxy-1-methacryloxyadamantane-co-ethylcyclopentylacrylate); poly(2-methyl-2-adamantyl methacrylate-co-3-hydroxy-1-adamantyl acrylate-co-α-gamma-butyrolactone methacrylate); poly(2-methyl-2-adamantyl methacrylate-co-3-hydroxy-1-methacryloxyadamantane-co-α-gamma-butyrolactone methacrylate-co-2-ethyl-2-adamantyl methacrylate); poly(2-methyl-2-adamantyl methacrylate-co-3-hydroxy-1-methacryloxyadamantane-co-β-gamma-butyrolactone methacrylate-co-tricyclo[5,2,1,0^{2,6}]deca-8-yl methacrylate); poly(2-methyl-2-adamantyl methacrylate-co-2-ethyl-2-adamantyl methacrylate-co-β-gamma-butyrolactone methacrylate-co-3-hydroxy-1-methacryloxyadamantane); poly(2-methyl-2-adamantyl methacrylate-co-2-ethyl-2-adamantyl methacrylate-co-α-gamma-butyrolactone methacrylate-co-3-hydroxy-1-methacryloxyadamantane); poly(2-methyl-2-adamantyl methacrylate-co-methacryloyloxy norbornene methacrylate-co-β-gamma-butyrolactone methacrylate); poly(ethylcyclopentylmethacrylate-co-2-ethyl-2-adamantyl methacrylate-co-α-gamma-butyrolactone acrylate); poly(2-ethyl-2-adamantyl methacrylate-co-3-hydroxy-1-adamantyl acrylate-co-isobutyl methacrylate-co-α-gamma-butyrolactone acrylate); poly(2-methyl-2-adamantyl methacrylate-co-β-gamma-butyrolactone methacrylate-co-3-hydroxy-1-adamantyl acrylate-co-tricyclo[5,2,1,02,6]deca-8-yl methacrylate); poly(2-ethyl-2-adamantyl methacrylate-co-3-hydroxy-1-adamantyl acrylate-co-α-gamma-butyrolactone acrylate); poly(2-methyl-2-adamantyl methacrylate-co--βgamma-butyrolactone methacrylate-co-2-adamantyl methacrylate-co-3-hydroxy-1-methacryloxyadamatane); poly(2-methyl-2-adamantyl methacrylate-co-methacryloyloxy norbornene methacrylate-co-β-gamma-butyrolactone methacrylate-co-2-adamantyl methacrylate-co-3-hydroxy-1-methacryloxyadamatane); poly(2-methyl-2-adamantyl methacrylate-co-methacryloyloxy norbornene methacrylate-co-tricyclo[5,2,1,02,6]deca-8-yl methacrylate-co-3-hydroxy-1-methacryloxyadamatane-co-α-gamma-butyrolactone methacrylate); poly(2-ethyl-2-adamantyl methacrylate-co-3-hydroxy-1-adamantyl acrylate-co-tricyclo[5,2,1,02,6]deca-8-yl methacrylate-co-α-gamma-butyrolactone methacrylate); poly(2-ethyl-2-adamantyl methacrylate-co-3-hydroxy-1-adamantyl acrylate-co-α-gamma-butyrolactone acrylate); poly(2-methyl-2-adamantyl methacrylate-co-3-hydroxy-1-methacryloxyadamatane-co-α-gamma-butyrolactone methacrylate-co-2-ethyl-2-adamantyl-co-methacrylate); poly(2-ethyl-2-adamantyl methacrylate-co-3-hydroxy-1-adamantyl acrylate-co-α-gamma-butyrolactone methacrylate-co-tricyclo[5,2,1,0^{2,6}]deca-8-yl methacrylate); poly(2-ethyl-2-adamantyl methacrylate-co-3-hydroxy-1-adamantyl acrylate-co-α-gamma-butyrolactone methacrylate); poly(2-methyl-2-adamantyl methacrylate-co-3-hydroxy-1-adamantyl acrylate-co-5-acryloyloxy-2,6-norbornanecarbolactone); poly(2-ethyl-2-adamantyl methacrylate-co-3-hydroxy-1-adamantyl acrylate-co-α-gamma-butyrolactone methacrylate-co-α-gamma-butyrolactone acrylate); poly(2-ethyl-2-adamantyl methacrylate-co-3-hydroxy-1-adamantyl acrylate-co-α-gamma-butyrolactone methacrylate-co-2-adamantyl methacrylate); and poly(2-ethyl-2-adamantyl methacrylate-co-3-hydroxy-1-adamantyl acrylate-co-α-gamma-butyrolactone acrylate-co-tricyclo[5,2,1,02,6]deca-8-yl methacrylate).

The photoresist may further comprise additives such as basic qenchers, surfactants, dyes, crosslinkers, etc. Useful photoresists are further exemplified and incorporated by reference in U.S. application with Ser. No. 11/834,490and US publication number US 2007/0015084.

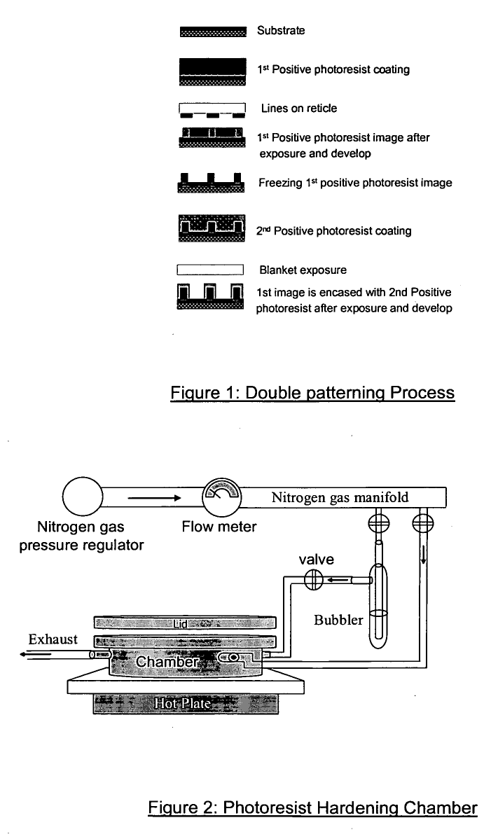

After the formation of the first photoresist pattern, the pattern is treated with a hardening compound to harden the photoresist so that the pattern becomes insoluble in the solvent of the second photoresist composition. In cases where the photoresist polymer has a glass transition temperature (Tg) lower than the hardening temperature of the photoresist alone, a hardening compound treatment is very useful, since lower temperatures than the Tg of the photoresist polymer can be used to harden the photoresist pattern. Photoresists comprising acrylate polymers are useful for hardening treatment of the present invention, since the Tg is lower than 200° C. In the present invention the hardening is done with a hardening amino compound comprising at least 2 amino (—NH₂) groups and simultaneously heating the photoresist pattern, thereby forming a hardened first photoresist pattern. Although not being bound by the theory, it is believed that the amino compound diffuses through the first photoresist pattern and in the presence of heat crosslinks the photoresist, thereby forming a hardened or frozen pattern. The pattern becomes insoluble in the solvent of the second photoresist composition. The hardening treatment may be done on a hot plate with a chamber or an enclosed oven, with the vapor of the hardening compound. The hardening of the first photoresist pattern may be done on a hotplate in an enclosed chamber where the amino compound is introduced in a vaporized form with a carrier gas like nitrogen, and the chamber further comprises a heating source to heat the patterned substrate in an enclosed atmosphere. In one case, the chamber comprises a hotplate for supporting the substrate, an inlet to introduce the amino compound, a purging inlet and an exhaust outlet. Purging may be done with nitrogen gas. FIG. 2 shows a typical chamber for hardening the pattern. Conditions such as the type of amino compound, the temperature and time of hardening, concentration of the amino compound, flow rate of the amino compound in a chamber, etc. are optimized to give the optimum degree of hardening. The extent of hardening can be determined by soaking the hardened photoresist in the test solvent to measure the loss of the film thickness of the treated photoresist. Minimal film thickness loss is desirable, where the film thickness loss of the treated photoresist in the solvent of the second photoresist is less than 10 nm, preferably less than 8 nm and more preferably less than 5 nm. Insufficient hardening will dissolve the first photoresist. Specifically, the solvent may be selected from the solvent(s) of the photoresist described herein as an example.

The hardening compound comprises at least 2 amino (NH₂) groups. The compound may be exemplified by structure (1),

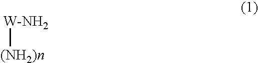

where, W is a C₁-C₈ alkylene, and n is 1-3. In one embodiment of the amino compound n=1. Alkylene may be linear or branched. Preferably alkylene is C₁-C₄. Examples of the amino compound are,

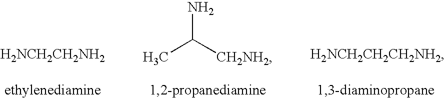

If the amino compound is used in a chamber, then a compound which can form a vapor is preferred. The amino compound may be used for hardening at temperatures in the range of about 25° C. to about 250° C., for about 30 seconds to about 20 minutes. Hardening temperature for shorter times can also be around the Tg of the photoresist polymer or around 0-10° C. below the Tg. The flow rate of the compound may range from about 1 to about 10 mL/minute. The vapor pressure of the amino compound and/or its temperature can be increased to accelerate the hardening reaction. The use of the amino compound allows for lower hardening temperatures and lower hardening times than just a thermal hardening alone of the first photoresist pattern.

An additional baking step may be included after the treatment step, which can induce further crosslinking and/or densification of the pattern and also to volatilize any residual gases in the film. The baking step may range in temperature from about 190° C. to about 250° C. Densification can lead to improved pattern profiles.

After the appropriate amount of hardening of the photoresist, the first photoresist pattern may optionally be treated with a cleaning solution. Examples of cleaning solutions can be edgebead removers for photoresists such as AZ®ArF Thinner or AZ®ArF MP Thinner available commercially, or any of the photoresist solvent(s).

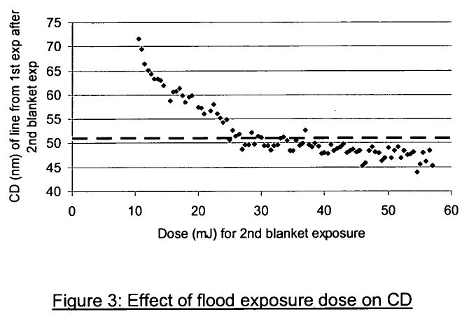

The first photoresist pattern is then coated to form a second layer of the second photoresist from a second photoresist composition. The second photoresist comprises a polymer, a photoacid generator and a solvent. The second photoresist may be the same or different than the first photoresist. The second photoresist may be chosen from any known photoresists, such as those described previously. The second photoresist is then flood exposed, and developed as described previously in a similar manner to the first photoresist. An edgebead remover may be used on the second photoresist layer after forming the coating. The energy required to flood expose the second photoresist layer is dependent on the degree of shrinking desired. The flood exposure dose is less than the exposure dose of the first photoresist. In one instance the flood exposure dose can range from 10-20 mJ/cm². The exact flood exposure dose can be determined by plotting a graph of dose against CD change of the photoresist, and the flood exposure dose used is determined by the increase in photoresist thickness required to make a device. At very low flood exposure doses, the CD is not effected, and as the flood exposure dose increases the CD decreases till a point where there is no further CD change. FIG. 3 shows such an effect. At current resolution targets it is desirable to obtain a space reduction of photoresist features obtained with the interface layer over the photoresist of between of from about 10 nm to about 60 nm, preferably about 20 nm to about 50 nm. The exact space width reduction requirement is highly dependent on the type of microelectronic devices being manufactured.

Once the desired narrow space is formed as defined by the process described above, the device may be further processed as required. Metals may be deposited in the space, the substrate may be etched, the photoresist may be planarized, etc.

Unless otherwise indicated, all numbers expressing quantities of ingredients, properties such as molecular weight, reaction conditions, and so forth used in the specification and claims are to be understood as being modified in all instances by the term “about.” Each of the documents referred to above are incorporated herein by reference in its entirety, for all purposes. The US patent application Docket Number 2008US304 filed Apr. 1, 2008 is also incorporated herein by reference in its entirety. The following specific examples will provide detailed illustrations of the methods of producing and utilizing compositions of the present invention. These examples are not intended, however, to limit or restrict the scope of the invention in any way and should not be construed as providing conditions, parameters or values which must be utilized exclusively in order to practice the present invention.

### EXAMPLES

Film thicknesses measurements were performed on a Nanospec 8000 using Cauchy's material-dependent constants derived on a J. A. Woollam® VUV VASE® Spectroscopic Ellipsometer. Photoresist on bottom antireflective coatings were modeled to fit the photoresist film thickness only.

CD-SEM measurements were done on either an Applied Materials SEM Vision or NanoSEM. Cross-sectional SEM images were obtained on a Hitachi 4700.

Lithography exposures were performed on a Nikon NSR-306D (NA: 0.85) interfaced to a Tokyo Electron Clean Track 12 modified to work with 8 in wafers as well. The wafers were coated with AZ® ArF-1C5D (a bottom antireflective coating available from AZ Electronic Materials USA Corps, Somerville, N.J., USA) and baked at 200° C./60sec to achieve 37 nm film thickness. Commercial AZ® AX2110 P (available from AZ Electronic Materials USA Corps, Somerville, N.J., USA) photoresist was diluted with AZ® ArF MP thinner (80:20 methyl-2-hydroxyisobutyrate:PGMEA) so that 90 nm film could be achieved with a coater spin rate of 1500 rpm. An attenuated PSM reticle (mask) with a large area grating composed of 1:1 90 nm Line/Space feature was overexposed to image approximately 45 nm lines using dipole illumination (0.82 outer, 0.43 inner sigma). The photoresist were soft baked at 100° C./60s and postexposure baked (PEB) at 110° C./60s. After PEB, the wafers were developed for 30 seconds with a surfactant-free developer, AZ® 300MIF (available from AZ Electronic Materials USA Corps, Somerville, N.J., USA), containing 2.38% tetramethyl ammonium hydroxide (TMAH).

The second exposure used the same photoresist composition and the same processing conditions as the first photoresist exposure above. No bottom antireflective coating (BARC) was necessary since the BARC from the 1st exposure remains. An open mask was used with the same field size and placement as was done in the first exposure.

### Vapor Reaction Chamber (VCR): For Freezing Photoresist Images

A schematic of the VRC is shown in Figure. The prototype freeze chamber was constructed of ½ inch gauge stainless steel. The 10 in diameter cylindrical wafer compartment has a removal lid that is sealed with a rubber gasket. The weight of the lid assures an intimate seal is made. The entire chamber rests on a 12×12 in Cimarec digital hot plate.

A freeze liquid is placed in a 250 mL gas washing bottle fitted with a porosity C fritted stopper. Nitrogen is bubbled thought the liquid and the freeze vapors are carried over the wafer in the heated reaction chamber. Gases are controlled by gas manifold valves and flow rates are monitored with a Riteflow flow meter. Unlike a prime chamber, no vacuum is used since the entire apparatus in setup in an inward airflow exhausted hood. Gases exiting the chamber are exhausted unrestricted into the rear of the hood so the overall pressure in the chamber is near atmospheric pressure.

Wafers processed through the chamber are manually placed into the chamber. The cover is placed on top and the nitrogen purge is switched to the freeze/nitrogen gas for a predetermined time after which the gas is switched back to pure nitrogen and the wafer is removed.

FIG. 2 shows the vapor reaction chamber (VRC) schematic. The chamber consists of 2 inlets, one for nitrogen purging the others for the nitrogen carrying the freeze vapors. A third port is used for exhausting. Chamber is heated with external hot plate.

### Image Hardening (Freeze) Tests

To investigate if a particular liquid was effective in freezing a photoresist a variety of test were performed.

Soak testing: This was performed by dispensing AZ ArF Thinner over the wafer until the wafer was entirely covered by a solvent puddle. After 30 seconds the wafer was spun at 500 rpm to remove the puddle while a dynamic dispense of fresh AZ ArF Thinner continued to dispense for 5 seconds at the center of the wafer. Finally, the spin rate was accelerated to 1500 rpm for 20 seconds to dry the wafer. When no freeze processing is done or an inadequate freeze liquid is used the 1st photoresist imaged is entirely removed leaving only the BARC behind. For those materials that are effective in freezing the photoresist image the film thickness was compared before and after soaking in the unexposed area. No difference in the film thickness after soaking shows that freezing is sufficient for double pattern processing

CD Measurements: The critical dimensions (CD) of the photoresist pattern in the patterned areas taken before and after the soak process are also indicators if the freeze process worked. If curing is not sufficient the features may swell or dissolve.

At times the wafers which were successfully frozen were subsequently processed through a high temperature bake and/or solvent wash to test the impact of post-processing on photoresist profiles. These processes were performed on the TEL track described above. The solvent wash was AZ®ArF Thinner.

### Example 1

The hardening gases were evaluated using the imaging process described above using only AZ® AX2110P photoresist. The hardening was conducted at various hotplate temperatures for different times using the VCR and according to the process described above. The hardened photoresist image was soaked in AZ ArF thinner as described above. Prior to the hardening process the CD of the first photoresist image was 38 nm. The CD was measured again after the hardening process was complete. A difference in CD before the hardening treatment and after the hardening treatment of about 8-10 nm is preferred. A large variation in the CD before and after the hardening process shows insufficient hardening which can lead to dissolution, swelling or flow of the pattern. The comparison of hardening materials is descried in Table 1.

TABLE 1
Evaluation of various hardening materials

| | | | Hardening | | |
|---|---|---|---|---|---|
| | | | Hotplate | | |
| | | Boiling | Bake | Hardening | CD (nm) after |
| | | point of | temperature | Bake time | hardening and |
| | Gas | gas (° C.) | (° C.) | (min) | solvent soak |
| 1 | 1,2-Diaminoethane | 118 | 100 | 20 | 39 |
| 2 | 1,2-Diaminoethane | 118 | 170 | 2 | 31** |
| 3 | 1,2-Diaminoethane | 118 | 190 | 2 | 81 |
| 4 | 1,2-Diaminoethane | 118 | 180 | 2 | 39 |
| 5 | 1,2-Diaminoethane | 118 | 180 | 4 | 42 |
| 6 | 1,3-Propanediamine | 140 | 180 | 2 | 39 |
| 7 | 1,3-Propanediamine | 140 | 180 | 4 | 45 |
| 8 | 1,5-Diamino-2- | 193 | 180 | 2 | 42 |
| | methylpentane | | | | |
| 9 | 1,5-Diamino-2- | 193 | 180 | 4 | 48* |
| | methylpentane | | | | |
| 10 | 1-Aminopentane | 104 | 180 | 4 | 65* |
| 11 | N-Methylbutylamine | 91 | 180 | 10 | 110* faint image |
| 12 | Triethylaamine | 89 | 180 | 10 | 100* faint image |
| 13 | Acetic acid | 117 | 180 | 10 | Image removed |
| 14 | Water | 100 | 180 | 10 | Image removed |

Initial CD 38 nm, VRC conditions, flow rate = 2500 mL/min,
*visual inspection reveals significant difference in film after soaking due to insufficient hardening, flowing or swelling.
**much of the film was removed, where patterns remained the CD was checked and was found to be smaller indicting the image is not completely frozen.

### Example 2

Hardening experiments using AZ AX 2110P alone and 1,2-Diaminoethane (DAE) hardening material are shown in the Table 2, using the same methodology as Example 1. The best hardening conditions was found to be around 100° C. bake temperature, 20 minutes bake with a 3 L/min DAE purge rate. With these conditions photoresist films showed no sign of dissolution after soaking using the soak test as described above. Shorter hardening times are possible with higher temperatures as is evident from the Example 1.

TABLE 2
Photoresist hardening in VRC using DAE

| | Hardening | Hardening | DAE | |
|---|---|---|---|---|
| | Bake temp | Bake time | flow | |
| AZ AX2110P | (° C.) | (min) | (L/min) | Film After Soak Test |
| film | None | None | None | completely soluble |
| film | 57 | 3 | None | completely soluble |
| film | 57 | 3 | 2 | completely soluble |
| film | 57 | 20 | 2 | completely soluble |
| film | 100 | 20 | 2 | completely soluble |
| Patterned Film | 100 | 20 | 2 | completely soluble |
| Patterned Film | 100 | 20 | None | completely soluble |
| Patterned Film | 57 | 180 | 3 | only a slight indication of soak line |
| Patterned Film | 57 | 180 | None | Mostly soluble |
| Patterned Film | 50 | 25 | 3 | Mostly soluble |
| Patterned Film | 100 | 60 | 3 | no indication of a soak line: |
| | | | | good hardening |
| Patterned Film | 100 | 20 | 3 | no indication of a soak line: |
| | | | | good hardening |
| Patterned Film | 100 | 5 | 3 | very slight indication of a soak line |
| Patterned Film | 100 | 5 | — | Mostly soluble |
| Patterned Film | 100 | 10 | 3 | very slight indication of a soak line |
| Patterned Film | 100 | 20 | 3 | no indication of a soak line: |
| | | | | good hardening |

Film coatings were prepared by spinning AZ ArF2110P photoresist at 1500 rpm and baking for 1 minute at 100° C. Patterned films were prepared the same way with the addition of a mask exposure, PEB and development as described in Example 1.

### Example 3

1^{st} Pattern Exposure: AZ AX2110P was coated on 37 nm of AZ 1C5D antireflective coating, exposed and developed as described above using a dose of 52 mJ/cm² at best focus. An example of the process margin for a 52 nm line is 0.3 microns depth of focus and 8% exposure latitude with 10% CD change. At 45 nm the DOF is about 0.2 microns. The 1st AZ AX 2110P image was frozen with the VRC process using DAE with a flow rate of 2.5 L/min and bake conditions of 180° C. for 2 min. The second layer of AZ AX2110P photoresist was directly coated over the hardened image and flood or blanket exposed with an open frame mask, and then developed with the photoresist process conditions used for the first exposure/develop. FIG. 3 shows the measurement of change in CD for an incremental increase in dose of 0.5 mJ/cm², starting at 5 mJ/cm².

The CD of the lines increased depending on the dose used in the blanket exposure as shown in FIG. 3. Data at low dose demonstrated the inverse relationship between dose and CD growth of a line after blanket exposure. The increased CD size corresponded to encasing of the first photoresist pattern by the second photoresist which can be controlled with dose of the blanket exposure. The increase in CD corresponds to a decrease in the space between the photoresist pattern.

FIG. 3: AX2110P photoresist was used in both exposures. 2^{nd} exposure used an open frame with the dose indicated in the x-axis. Dotted lines in bottom graph represent the reference CD after VRC process only but no flood exposure step.

1. A process for forming a photoresist pattern on a device, comprising;
a) forming a layer of first photoresist on a substrate from a first photoresist composition;
b) imagewise exposing the first photoresist;
c) developing the first photoresist to form a first photoresist pattern;
d) treating the first photoresist pattern with a hardening compound comprising at least 2 amino (NH₂) groups, thereby forming a hardened first photoresist pattern;
e) forming a second photoresist layer on the region of the substrate including the hardened first photoresist pattern from a second photoresist composition;
f) flood exposing the second photoresist; and,
g) developing the photoresist pattern, thereby forming a photoresist pattern with increased dimensions and reduced space.

2. The process of claim 1, where the hardening compound has structure (1), 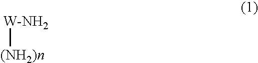
where, W is a C₁-C₈ alkylene, and n is 1-3.

3. The process of claim 1, where the hardening compound is selected from 1,2-diaminoethane, 1,3-propanediamine, and 1,5-diamino-2-methylpentane.

4. The process of claim 2, where n is 1.

5. The process of claim 1, where the treating step of the first photoresist pattern is with a vaporized hardening compound.

6. The process of claim 1, where the treating step comprises heating step.

7. The process of claim 6, where the heating step is in the range of about 80° C. to about 225° C.

8. The process of claim 1, where the first photoresist composition and the second photoresist composition are the same.

9. The process of claim 1, where the photoresists are selected from negative or positive.

10. The process of claim 1, where the first photoresist is a chemically amplified photoresist.

11. The process of claim 1, where the first photoresist composition comprises a polymer, photoacid generator and a solvent.

12. The process of claim 9, where the polymer is a (meth)acrylate polymer.

13. The process of claim 1, where after the hardening step the first photoresist is insoluble in solvent of the second photoresist composition.

14. The process of claim 1, where the loss in thickness of the first photoresist pattern in the solvent of the second photoresist is less than 10 nm.

15. The process of claim 13, where the solvent of the second photoresist composition is selected from PGMEA, PGME, ethyl lactate and mixtures thereof.

16. The process of claim 1, where the imagewise exposure is selected from 193 nm, 248 nm, 365 nm and 436 nm.

17. The process of claim 1, where the developing is with an aqueous alkaline developer.

18. The process of claim 1, further comprising a baking step after the treatment step.

19. The process of claim 1, further comprising a step of solvent cleaning the hardened pattern prior to forming the second photoresist layer.

20. A product using the process of claim 1.

21. A microelectronic device formed by using a process for forming a photoresist pattern on a device, comprising;
a) forming a layer of first photoresist on a substrate from a first photoresist composition;
b) imagewise exposing the first photoresist;
c) developing the first photoresist to form a first photoresist pattern;
d) treating the first photoresist pattern with a hardening compound comprising at least 2 amino (NH₂) groups, thereby forming a hardened first photoresist pattern;
e) forming a second photoresist layer on the region of the substrate including the hardened first photoresist pattern from a second photoresist composition;
f) flood exposing the second photoresist; and,
g) developing the photoresist pattern, thereby forming a photoresist pattern with increased dimensions and reduced space.
